(19) United States
(12) Patent Application Publication
(10) Pub. No.: US 2013/0154095 A1
(43) Pub. Date: Jun. 20, 2013

(54) SEMICONDUCTOR DEVICES CONNECTED BY ANISOTROPIC CONDUCTIVE FILM COMPRISING CONDUCTIVE MICROSPHERES

(71) Applicants: Arum YU, Uiwang-si (KR); Nam Ju KIM, Uiwang-si (KR); Kyoung Soo PARK, Uiwang-si (KR); Young Woo PARK, Uiwang-si (KR); Joon Mo SEO, Uiwang-si (KR); Motohide TAKEICHI, Uiwang-si (KR); Dong Seon UH, Uiwang-si (KR); Hyun Min CHOI, Uiwang-si (KR)

(72) Inventors: Arum YU, Uiwang-si (KR); Nam Ju KIM, Uiwang-si (KR); Kyoung Soo PARK, Uiwang-si (KR); Young Woo PARK, Uiwang-si (KR); Joon Mo SEO, Uiwang-si (KR); Motohide TAKEICHI, Uiwang-si (KR); Dong Seon UH, Uiwang-si (KR); Hyun Min CHOI, Uiwang-si (KR)

(21) Appl. No.: 13/720,051

(22) Filed: Dec. 19, 2012

(30) Foreign Application Priority Data
Dec. 20, 2011 (KR) 10-2011-0138246

(51) Int. Cl. H01L 23/00

(52) U.S. Cl. CPC H01L 24/29
USPC 257/746

(57) ABSTRACT

A semiconductor device includes an anisotropic conductive film for connecting the semiconductor device. The anisotropic conductive film includes a first conductive layer that has first conductive particles. The first conductive particles include cores containing silica or a silica composite, and have a 20% K-value ranging from about 7,000 N/mm² to about 12,000 N/mm².

### CROSS-REFERENCE TO RELATED APPLICATION

This application claims priority under 35 U.S.C. §119 to Korean Patent Application No. 10-2011-0138246 filed on Dec. 20, 2011, in the Korean Intellectual Property Office, and entitled: “Semiconductor Devices Connected by Anisotropic Conductive Film Comprising Conductive Microspheres,” which is incorporated by reference herein in its entirety.

### BACKGROUND

Anisotropic conductive adhesives may be used to connect electronic components such as semiconductor devices to a circuit board. For example, the anisotropic conductive adhesives may be used for forming connections in various displays such as liquid crystal displays (LCDs) and organic light-emitting devices (OLEDs).

### SUMMARY

Embodiments may be realized by providing a semiconductor device that includes an anisotropic conductive film for connecting the semiconductor device, and the anisotropic conductive film includes a first conductive layer having first conductive particles. The first conductive particles include cores containing silica or a silica composite, and have a 20% K value ranging from about 7,000 N/mm² to about 12,000 N/mm².

The first conductive particles may have a compressive strain ranging from about 5% to about 40% upon thermal compression of the anisotropic conductive film under conditions of 220° C. and 110 Mpa for 5 seconds. The cores may include the silica composite and the silica composite may include a polymer resin and silica. The polymer resin may be a polymer of at least one monomer selected from the group of a crosslinking polymerizable monomer and a mono-functional monomer.

The polymer resin may include the crosslinking polymerizable monomer, and the crosslinking polymerizable monomer may include at least one selected from the group of a vinyl benzene monomer, allyl compound monomer and an acrylate monomer. The polymer resin may include the mono-functional monomer, and the mono-functional monomer may include at least one selected from the group of a styrene monomer, a (meth)acrylate monomer, vinyl chloride, vinyl acetate, vinyl ether, vinyl propionate, and vinyl butyrate.

The silica composite may include about 15 wt % to about 90 wt % of silica based on a total amount of the silica composite. The first conductive particles may have an average particle diameter of about 0.1 μm to about 200 μm. The first conductive particles may include conductive shells on the cores. The first conductive particles may have protrusions on surfaces thereof.

The anisotropic conductive film may further include second conductive particles having a second 20% K-value different from the 20% K-value of the first conductive particles, and the second 20% K-value may range from about 3,000 N/mm² to about 7,000 N/mm². A difference between the 20% K-value of the first conductive particles and the second 20% K-value of the second conductive particles may be less than about 5,000 N/mm².

The second conductive particles may have cores including a polymer resin. The first conductive particles may have about 10 to about 40 protrusions per unit surface area on surfaces thereof. The second conductive particles may have 0 to about 10 protrusions per unit surface area on surfaces thereof. The second conductive particles may be present in an amount of about 1 to about 30 parts by weight based on 100 parts by weight of a total amount of conductive particles.

The anisotropic conductive film may further include a second conductive layer on the first conductive layer. The second conductive layer may include second conductive particles, and a first hardness of the first conductive particles may be higher that a second hardness of the second conductive particles. A difference between the 20% K-value of the first conductive particles and a second 20% K-value of the second conductive particles may be about 5,000 N/mm² or more. A first surface roughness of the first conductive particles may be greater that a second surface roughness of the second conductive particles.

Embodiments may also be realized by providing a semiconductor device that includes a wiring substrate having a metal and metal oxide layer placed on an outermost layer thereof, an anisotropic conductive film attached to a chip mounting surface of the wiring substrate, and a semiconductor chip mounted on the anisotropic conductive film. The anisotropic conductive film directly adjoins the metal and metal oxide layer and includes a first conductive layer including first conductive particles, and the first conductive particles have a 20% K-value from about 7,000 N/mm² to about 12,000 N/mm², and have a compressive strain from about 5% to about 40% upon thermal compression of the anisotropic conductive film under conditions of 220° C. and 110 Mpa for 5 seconds.

The anisotropic conductive film may further include second conductive particles having a second 20% K value that is lower than the 20% K value of the first conductive particles. The anisotropic conductive film may include a second conductive layer on the first conductive layer, and the second conductive layer may include second conductive particles that have a second 20% K-value that is lower than the 20% K value of the first conductive particles. The first conductive particles may include protrusions on surfaces thereof.

### BRIEF DESCRIPTION OF THE DRAWINGS

Features will become apparent to those skilled in the art by describing in detail exemplary embodiments with reference to the attached drawings in which:

FIG. 1 illustrates first conductive particles having high hardness to provide low deformability and second conductive particles having low hardness to provide good visibility, in which a right side picture is an enlarged view of a left side picture;

FIG. 2 illustrates evaluation results of Experimental Example 2;

FIG. 3 illustrates an explanation of a measurement apparatus for measuring hardness of conductive particles using a nano-indenter;

FIG. 4 illustrates an image of first conductive particles having high surface roughness in accordance with an exemplary embodiment;

FIG. 5 illustrates an image of second conductive particles having low surface roughness in accordance with an exemplary embodiment;

FIG. 6 illustrates an image of one example of conductive particles exhibiting good post-bonding visibility (Example 4); and

FIG. 7 illustrates an image of one example of conductive particles exhibiting poor post-bonding visibility (Comparative Example 8).

FIGS. 8 and 9 illustrate exemplary embodiments of anisotropic conductive films.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

An exemplary embodiment includes a semiconductor device connected by an anisotropic conductive film, in which the anisotropic conductive film may include a first conductive layer having first conductive particles. The first conductive particles may include cores that contain silica and/or a silica composite, and the first conductive particles may have a 20% K-value ranging from about 7,000 N/mm² to about 12,000 N/mm².

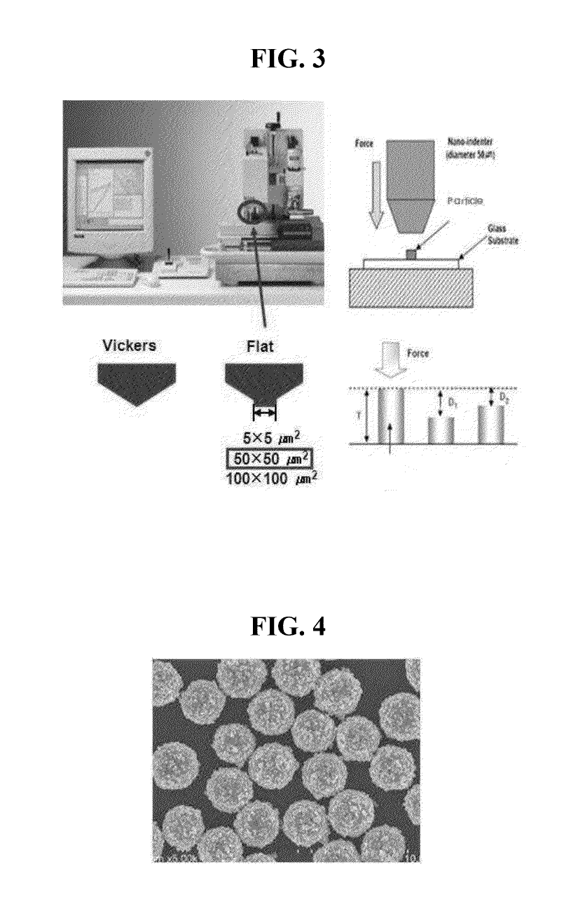

According to an exemplary embodiment, a hardness characteristic of conductive particles will be expressed by a K-value. Determining the hardness may include obtaining a load upon deformation of a single conductive particle using a nano-indenter (see FIG. 3) and calculating the K-value based on the load according to Equation 1

K-value(N/mm²)=(3/2^{1/2})·F·S^{-3/2}·R^{-1/2} [Equation 1]

wherein F is a load (e.g., in Newtons) upon compressive deformation of a conductive particle, S is a compressive displacement (e.g., mm) of the conductive particle upon compression deformation thereof, and R is a radius (e.g., mm) of the conductive particle.

As used herein, the term “20% K-value” means the K-value when S/2R=0.2.

According to an exemplary embodiment, the first conductive particles have a 20% K-value ranging from about 7,000 N/mm² to about 12,000 N/mm², e.g., from about 8,000 N/mm² to about 11,000 N/mm². However, embodiments are not limited thereto, e.g., the 20% K-value may range from about 9,500 N/mm² to about 10,500 N/mm², from about 9,000 N/mm² to about 11,000 N/mm², etc.

Within this range of the 20% K-value, it may be possible to obtain conductive particles that have sufficient hardness to penetrate a metal oxide layer for connection and to obtain high hardness conductive particles that exhibit slight deformability. For example, the first conductive particles may have a compressive strain of about 5% to about 40% upon thermal compression under conditions of, e.g., 220° C. and 110 MPa for 5 seconds.

The radius R of the conductive particle may be an initial radius. For example, the radius R may be measured before deformation of the single conductive particle.

According to an exemplary embodiment, the first conductive particles may include any core allowing the conductive particles to have a 20% K-value of about 7,000 N/mm² to about 12,000 N/mm². For example, the first conductive particles may include cores containing silica (SiO₂) or a silica composite.

In some embodiments, the cores of the first conductive particles may include at least silica. As used herein, the silica composite for the cores of the first conductive particles refers to a composite of a polymer resin and silicon oxide (SiO₂).

In the composite of the polymer resin and silica, the polymer resin may include a polymer of at least one monomer selected from the group of crosslinking polymerizable monomers and monofunctional monomers. The polymer resin may be present in an amount of about 10 wt % to about 85 wt % based on a total weight of the composite. The polymer resin may be highly cross-linked organic polymer particles having a high degree of crosslinking. The silica may be present in an amount of about 15 w% to about 90 wt % based on the total weight of the composite. The silica may represent the remainder of the composite. The silica may be dispersed throughout, e.g., randomly throughout, the polymer resin in the composite.

For example, the crosslinking polymerizable monomer may include at least one selected from the group of vinyl benzene monomers such as divinyl benzene; allyl compounds such as 1,4-divinyloxybutane, divinyl sulfone, diallyl phthalate, diallyl acrylamide, triallyl (iso)cyanurate, and triallyl trimellitate; acrylate monomers, such as ethylene glycol di(meth)acrylate, propylene glycol di(meth)acrylate, pentaerythritol tetra(meth)acrylate, pentaerythritol tri(meth)acrylate, pentaerythritol di(meth)acrylate, trimethylolpropane tri(meth)acrylate, dipentaerythritol hexa(meth)acrylate, dipentaerythritol penta(meth)acrylate, and glycerol tri(meth)acrylate, and the like, without being limited thereto.

For example, the mono-functional monomer may include at least one selected from the group of styrene monomers, such as styrene, methylstyrene, m-chloromethylstyrene, and ethylstyrene; (meth)acrylate monomers, such as methyl(meth)acrylate, ethyl(meth)acrylate, propyl(meth)acrylate, n-butyl(meth)acrylate, isobutyl(meth)acrylate, t-butyl(meth)acrylate, 2-ethylhexyl(meth)acrylate, n-octyl(meth)acrylate, lauryl(meth)acrylate, and stearyl(meth)acrylate; vinyl monomers such as vinyl chloride, vinyl acetate, vinyl ether, vinyl propionate, vinyl butyrate, and the like, without being limited thereto.

The silica composite may be obtained by adding silica to the polymer resin. With the inclusion of the silica, the polymer resin may have significantly improved physical properties in terms of, e.g., strength, stiffness, and wear resistance. Accordingly, the silica composite may be much harder than other typical polymer resins. According to an exemplary embodiment, the silica composite may be used as the core for conductive particles that are formed to penetrate a metal oxide layer for connection within OLEDs.

The first conductive particle may further include a conductive shell formed on the core, which core contains silica or the silica composite. The first conductive particles may be prepared as a single kind of conductive particle or by mixing two or more kinds of conductive particles. The first conductive particles may have an average particle size ranging from about 0.1 μm to about 200 μm.

In an implementation, each of the first conductive particles may include protrusions formed on a surface thereof. For example, the first conductive particle may include about 10 to about 40 protrusions per unit surface area (1 μm²) thereof, e.g., about 15 to about 30 protrusions per unit surface area. Within this range, the first conductive particles may exhibit excellent connection performance.

In exemplary embodiments, a semiconductor device may be connected by an anisotropic conductive film, which anisotropic conductive film includes both the first conductive particles and second conductive particles. For example, the first conductive particles may be included in a first conductive layer, and the second conductive particles may be included in a second conductive layer so that the first and second conductive layers are discrete layers. For example, referring to FIG. 8, a first conductive layer 100 has a second conductive layer 200 stacked thereon to form a single anisotropic conductive film. According to another exemplary embodiment, the first conductive particles may be intermixed with the second conductive particles within the first conductive layer. For example, referring to FIG. 9, the anisotropic conductive film includes a first conductive layer 300, which includes both the first conductive particles and the second conductive particles.

The first conductive particles may include cores containing silica or the silica composite and a 20% K-value ranging from, e.g., about 7,000 N/mm² to about 12,000 N/mm². The second conductive particles may have a 20% K-value ranging from about 3,000 N/mm² to about 7,000 N/mm². A difference in 20% K-value between the first conductive particles and the second conductive particles may be less than about 5,000 N/mm². Further, the 20% K-value for the first conductive particles may be greater than the 20% K-value for the second conductive particles.

In this embodiment, the second conductive particles may have a 20% K-value ranging from about 3,000 N/mm² to about 7,000 N/mm², e.g., about 4,500 N/mm² to about 6,500 N/mm². Within this range, the conductive particles may exhibit suitable deformability.

In this embodiment, the first conductive particles included in the first conductive layer may have a high hardness and may act as flow passages of electric current between circuit terminals. The first conductive particles may not exhibit the characteristics of damage and/or deformation thereof upon compression. Accordingly, the first conductive particles may provide hardness to the anisotropic conductive film. The second conductive particles, e.g., included in the second conductive layer or included in the first conductive layer with the first conductive particles, may be easily broken or deformed upon compression. Accordingly, the second conductive parties may allow a degree of compression of the anisotropic conductive film to be confirmed, e.g., to allow for identification of a connection result of the anisotropic conductive film.

The second conductive particles may be present in an amount of about 1 to about 30 parts by weight based on 100 parts by weight of all of the conductive particles. The first conductive particles may represent a remainder of the weight of all of the conductive particles, e.g., the first conductive particles may be present in an amount of about 70 to about 99 parts by weight based on 100 parts by weight of all of the conductive particles. Accordingly, an amount of the first conductive particles in the anisotropic conductive film may be greater than the amount of second conductive particles.

The difference in 20% K-value between the first conductive particles and second conductive particles may be greater than 0 to less than about 5,000 N/mm². When the difference in 20% K-value therebetween is less than about 5,000 N/mm², an increase in connection resistance due to excessive differences between the first and second conductive particles may be avoided, thereby deterioration in connection performance may not be observed. If the first and second conductive particles have a same 20% K-value, a difference in hardness is not realized.

The second conductive particles may include suitable conductive particles, which may include conductive particles that have a 20% K-value ranging from about 3,000 N/mm² to about 7,000 N/mm², or exhibit a similar level of hardness.

Examples of the second conductive particles may include at least one selected from the group of metallic particles including Au, Ag, Ni, Cu, solder, and the like; carbon particles; metal-coated resin particles prepared by coating resin particles, such polyethylene, polypropylene, polyester, polystyrene, and polyvinyl alcohol resin particles, or modified resin particles thereof with metal such as Au, Ag, Ni, and the like; and insulation-treated conductive particles prepared by coating such conductive particles with insulator particles, without being limited thereto. According to an exemplary embodiment, the second conductive particles may include cores of a polymer resin, e.g., a polymethyl methacrylate and/or a polysiloxane resin.

The second conductive particles may be prepared as a single kind of conductive particle or by mixing two or more kinds of conductive particles.

In exemplary embodiments, the first conductive particles included in the first conductive layer may have high hardness and may act as flow passages of electric current between circuit terminals without damage or deformation of the first conductive particles upon compression. Further, the second conductive particles included in the second conductive layer may be easily broken or deformed upon compression, thereby allowing the degree of compression of the anisotropic conductive film to be confirmed.

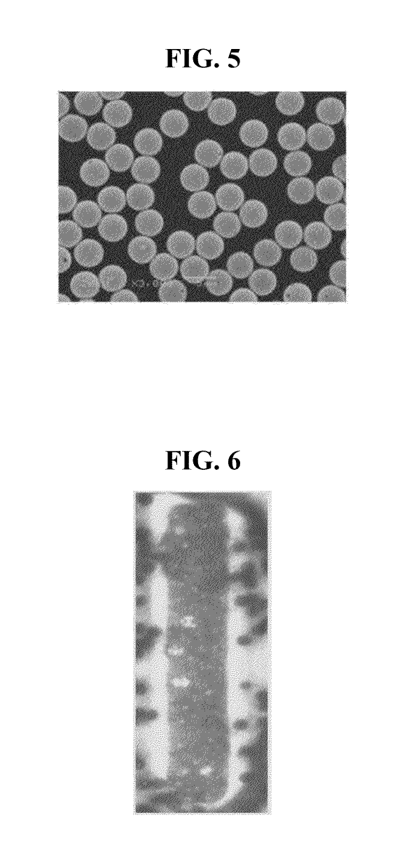

The first conductive particles may have a higher surface roughness (see FIG. 4) than that of the second conductive particles (see FIG. 5). For example, referring to FIG. 4, the first conductive particles may have the protrusions formed on a surface thereof to form a rough outer surface having a high surface roughness. Referring to FIG. 5, the second conductive particles may appear smoother, e.g., the second conductive particles may substantially exclude surface protrusions so as to be substantially smooth.

When the surface roughness of the second conductive particles is lower than the surface roughness of the first conductive particles, it is possible to improve visibility of the particles by reducing and/or preventing diffuse reflection of light. The surface roughness of the first and second conductive particles may be determined according to various factors such as materials and preparation methods thereof. For example, when the protrusions are formed on the surfaces of the first conductive particles, the first conductive particles may have increased surface roughness. Each of the protrusions of the first conductive particles may protrude at a height of about 0.1 μm or more, e.g., 0.2 μm or more, from an outer surface of the corresponding conductive particle. The protrusions may protrude from the conductive shell formed on the core containing the silica or the silica composite of the first conductive particles.

Various processes, e.g., any process that which is a in the art, may be used to form the protrusions on the surfaces of the conductive particles, without limitation. For example, electroless plating may be performed by dipping microspheres of a core-conductive shell structure of the first conductive particles into an electroless plating solution containing a metal salt solution and a reducing agent.

The first conductive particle may include about 10 to about 40 protrusions per unit surface area (1 μm²) thereof, e.g., about 15 to about 30 protrusions per unit surface area. Within this range, the first conductive particles may exhibit excellent connection performance.

The second conductive particles may have protrusions or may not have protrusions on the surfaces thereof. In the case that the second conductive particles include protrusions, the second conductive particles may include a lesser amount of protrusions than the first conductive particles.

The second conductive particle may include 0 to about 10 protrusions per unit surface area (1 μm²) thereof, e.g., 0 to about 5 protrusions per unit surface area. Within this range of the protrusions, it is possible to confirm suitable connection upon bonding of the conductive film, thereby providing excellent visibility to confirm suitable bonding pressure while reducing connection resistance through operation of the protrusions.

As used herein, the term “visibility” related to the particles refers to properties of an object allowing an observer to view the object with the naked eye or using a microscope. In addition, as used herein, the term “visibility” related to the second conductive particles refer to properties of conductive particles allowing an observer to observe deformation of the conductive particles in order to confirm whether suitable connection is obtained upon bonding of the anisotropic conductive film.

Since the second conductive particles have relatively low hardness compared to the first conductive particles, the second conductive particles may facilitate confirmation of a suitable connection of the anisotropic conductive film through easy deformation, that is, excellent visibility with respect to observing a connection result.

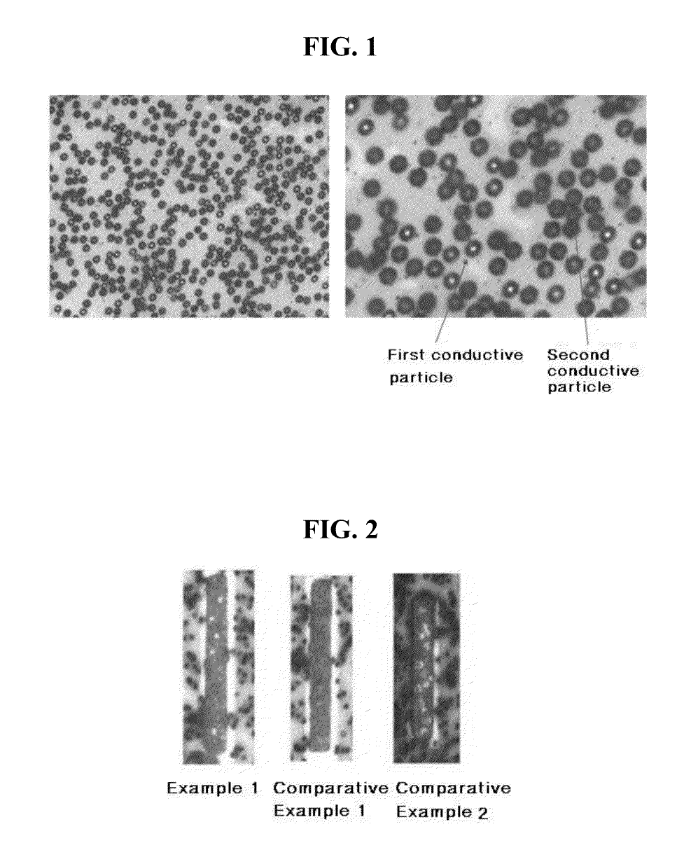

For example, when observing conductive particles having large number of protrusions formed on the surfaces thereof using a microscope or the like, the surfaces of the conductive particles appear dark, thereby making it difficult to observe deformation of the conductive particles. On the other hand, when observing conductive particles having no protrusions or small amounts of protrusions formed on the surfaces thereof, the surfaces of the conductive particles appear bright, thereby facilitating observation of deformation thereof (see FIG. 1 and FIG. 2).

In a further exemplary embodiment, a semiconductor device may be connected by an anisotropic conductive film, in which the anisotropic conductive film includes a first conductive layer including first conductive particles, and a second conductive layer formed on the first conductive layer and including second conductive particles. The first conductive particles may include cores containing silica or a silica composite and may have a 20% K-value ranging from about 7,000 N/mm² to about 12,000 N/mm². The first conductive particles may have a higher hardness than the second conductive particles.

In this exemplary embodiment, the difference in 20% K-value between the first conductive particles and the second conductive particles may be about 5,000 N/mm² or more. The second conductive particles may be easily broken or deformed upon compression, thereby improving visibility of the conductive particles by allowing the degree of compression of the anisotropic conductive film to be confirmed. When the difference in 20% K-value therebetween is greater than or equal to about 5,000 N/mm², the anisotropic conductive film may be easily deformed upon compression, thereby facilitating improvement of visibility.

In this embodiment, the first conductive particles included in the first conductive layer may have high hardness and may act as flow passages of electric current between circuit terminals without damage or deformation of the particles upon compression. The second conductive particles included in the second conductive layer may be easily broken or deformed upon compression, thereby allowing the degree of compression of the anisotropic conductive film to be confirmed.

When both the first conductive particles and the second conductive particles are included in a single layer of the anisotropic conductive film, the second conductive particles may deteriorate flowability and tack of a composition for the anisotropic conductive film and dispersibility during a process. As a result, e.g., due to the deteriorated flowability of the composition, temperature may be increased upon pre-compression in order to obtain desired pre-compression performance. Thus, the first and second conductive particles may be included in the first and second conductive layers, respectively, in terms of dispersibility, pre-compression temperature, viscosity, and flowability.

For example, as the second conductive particles are included in the second conductive layer, the first conductive particles may have an improved degree of dispersion in the first conductive layer. The degree of dispersion of the anisotropic conductive film may be obtained by particle density. The anisotropic conductive film may have a degree of dispersion ranging from about 20,000 to about 70,000, e.g., from about 30,000 to about 60,000. The degree of dispersion may be confirmed by the density of particles after film coating, and the density of particles is calculated by the following Equation 2 based on the number of particles counted by KAMSCOPE after photographing the particles using a microscope.

Degree of dispersion=(Number of second conductive particles/Number of first conductive particles)×100 <Equation 2>

In an exemplary embodiment, the first conductive particles may be present in an amount of about 1 wt % to about 30 wt % based on a total amount of the composition for forming the first conductive layer. The second conductive particles may be present in an amount of about 1 wt % to about 30 wt % based on a total amount of the composition for forming the second conductive layer.

The first conductive particles and/or second conductive particles may be prepared by coating core compounds with conductive metals. The core compound for the first conductive particles may have a higher hardness than the core compound for the second conductive particles. For example, the core compound for the first conductive particles may be any core compound that provides a 20% K-value of about 7,000 N/mm² to about 12,000 N/mm² to the conductive particles. According to an exemplary embodiment, the core compound for the first conductive particles may include silica (SiO₂) or a silica composite.

The core compound for the second conductive particles may include at least one resin, such as epoxy, melamine, urethane, benzoguanamine, phenol, poly olefin, polyether, polyester, polystyrene, NBR, SBR, BR, polyvinyl alcohol, and polysilicone resins, or modified resins thereof. According to another embodiment, the second conducive particles may be prepared by coating such resin particles with at least one metal such as gold, silver, nickel, copper, palladium, solder, and the like. The second conductive particles may be prepared using at least one selected from among these core compounds.

In yet another exemplary embodiment, a semiconductor device may be connected by an anisotropic conductive film, in which the anisotropic conductive film includes a first conductive layer including first conductive particles, and a second conductive layer formed on the first conductive layer and including second conductive particles. The first conductive particles may include cores containing silica or a silica composite and may have a 20% K-value ranging from about 7,000 N/mm² to about 12,000 N/mm². The first conductive particles may have a higher surface roughness than the second conductive particles.

In this embodiment, the surface roughness of the first conductive particles (see FIG. 4) may be greater than that of the second conductive particles (see FIG. 5). When the surface roughness of the second conductive particles is lower than the surface roughness of the first conductive particles, it may be possible to improve visibility of the particles by reducing and/or preventing diffuse reflection of light.

In this embodiment, the surface roughness of the first and second conductive particles may be confirmed through SEM analysis.

The surface roughness of the first and second conductive particles may be determined according to various factors such as materials and preparation methods thereof. For example, when protrusions are formed on the surfaces of the first conductive particles, the first conductive particles may have increased surface roughness. For example, any process known in the art may be used to form the protrusions on the surfaces of the conductive particles, without limitation.

An exemplary method of forming the protrusions includes electroless plating, which may be performed by dipping microspheres of a core-conductive shell structure into an electroless plating solution containing a metal salt solution and a reducing agent. Each of the protrusions of the first conductive particles may protrude at a height of about 0.1 μm or more, e.g., about 0.2 μm or more, from an outer surface of the corresponding conductive particle.

In this embodiment, the first and second conductive particles having different hardness may have an average particle diameter depending on the pitch of circuits. For example, the first and second conductive particles may have an average particle diameter of about 2 μm to about 30 μm, e.g., about 2 μm to about 6 μm. The first conductive particles may have the same or different particle diameter than the second conductive particles. When the circuit has a fine pitch, the first conductive particles have a smaller average particle diameter than the second conductive particles.

In this embodiment, the first conductive particles may be present in an amount of about 1 wt % to about 30 wt % based on the total amount of the composition for the first conductive layer, and the second conductive particles may be present in an amount of 1 wt % to 30 wt % based on the total amount of the composition for the second conductive layer.

The first conductive particles may include about 10 to about 40 protrusions per unit surface area (1 μm²) thereof, e.g., about 15 to about 30 protrusions per unit surface area. Within this range, the first conductive particles may exhibit excellent connection performance.

The second conductive particles may or may not have protrusions on the surfaces thereof. The second conductive particle may include 0 to about 10 protrusions per unit surface area (1 μm²) thereof, e.g., 0 to about 5 protrusions per unit surface area. Within this range of the protrusions, it may be possible to confirm suitable connection upon bonding of the conductive film, thereby providing excellent visibility to confirm suitable bonding pressure while possibly reducing connection resistance via the protrusions.

In an exemplary embodiment of using an anisotropic conductive film according to embodiments, a semiconductor device may include a wiring substrate having a metal and metal oxide layer placed on the outermost layer thereof, the anisotropic conductive film attached to a chip mounting surface of the wiring substrate, and a semiconductor chip mounted on the anisotropic conductive film. The anisotropic conductive film may directly adjoin the metal and metal oxide layer, and may include a first conductive layer including first conductive particles. The first conductive particles may have a 20% K-value ranging from about 7,000 N/mm² to about 12,000 N/mm² and a compressive strain ranging from about 5% to about 40% upon thermal compression at 220° C. under a load of 110 Mpa for 5 seconds.

To enhance the possibility of achieving a stable maximization of a contact area between electrodes, while providing suitable connection between the electrodes, it is sought for the conductive microsphere to exhibit high hardness at an initial stage of compression and to be suitably deformed as compression proceeds.

According to this embodiment, the conductive microspheres may have a 20% K-value from about 7,000 N/mm² to about 12,000 N/mm², e.g., from about 8,000 N/mm² to about 11,000 N/mm². Within this range of the 20% K-value, the conductive microspheres may provide suitable connection through metal at the uppermost layer of a terminal on a panel. If the 20% K-value of the conductive microspheres is equal to or greater than about 7,000 N/mm², the conductive microspheres may be sufficiently hard and may provide a suitable connection through a metal oxide layer of the terminal. Accordingly, a stable connection may result. If the 20% K-value of the conductive microspheres equal to or less than about 12,000 N/mm², the conductive microspheres interposed between the electrodes may be easily deformed, such that the contact area between the electrode surface and the conductive microspheres may be sufficiently enlarged, and it possible to decrease connection resistance.

If the compressive strain is less than about 5%, compressive force may be directly transferred to each of the panel and a driver IC, causing physical damage thereof, thereby causing connection failure. If the compressive strain exceeds about 40%, it may be difficult for the conductive microspheres to be sufficiently recovered upon contraction/expansion of adhesives by external heat. Accordingly, a gap may be undesirably generated between the conductive microspheres and the electrode surface.

The compressive strain may be calculated by the following equation:

compressive strain=(R1−R2)/(R1+R2)×100,

wherein R1 and R2 indicate a horizontal diameter and a vertical diameter of a particle, respectively, when the particle is deformed upon thermal compression of an anisotropic conductive film at 220° C. under a load of 110 MPa for 5 seconds.

In this embodiment, the first conductive particles may include cores containing silica or a silica composite. When the silica is added to a polymer resin, the polymer resin may have significantly enhanced strength, stiffness, and wear resistance. Further, as compared with the case where silica composite are used as the cores, the first conductive particles including the polymer resin have a certain degree of elasticity and thus may exhibit flexible compression and deformation in a connection space.

In an exemplary embodiment, SiO₂ may be present in an amount of about 15 wt % to about 90 wt % based on the total amount of the composite of the polymer resin and SiO₂. Within this range, the conductive microspheres may have desired hardness and connection reliability.

In this embodiment, the first conductive layer may further include second conductive particles, which have a lower 20% K-value than the first conductive particles.

Further, in this embodiment, the anisotropic conductive film may further include a second conductive layer, which is formed on the first conductive layer and includes second conductive particles having a lower 20% K-value than the first conductive particles. The first conductive particles may have protrusions formed on surfaces thereof.

The composition for the anisotropic conductive film may further include an insulation adhesive component and a curing agent. As for the insulation adhesive component, any typical component used in compositions for anisotropic conductive films may be used without limitation. For example, the insulation adhesive component may include at least one selected from the group of olefin resins, such as polyethylene, polypropylene, and the like; butadiene resins, an acrylonitrile butadiene copolymer, a carboxyl terminated acrylonitrile butadiene copolymer, polyimide resins, polyamide resins, polyester resins, polyvinyl butylal resins, ethylene-vinyl acetate copolymers, styrene-butylene-styrene (SBS), styrene-ethylene-butylene-styrene (SEBS), acrylonitrile butadiene rubber (NBR), epoxy resins, urethane resins, (meth)acrylic resins, phenoxy resins, and the like, without being limited thereto. These may be used alone or in combination thereof.

The curing agent may promote a curing reaction, thereby ensuring adhesion between connection layers and connection reliability. The curing agent may include a radical curable unit selected from mono-functional or poly-functional (meth)acrylate oligomers and monomers. For example, a bi-functional (meth)acrylate monomer or oligomer may be used as the curing agent.

The curing system may include at least one selected from epoxy (meth)acrylate resins, the intermolecular structure of which includes a backbone of 2-bromohydroquinone, resorcinol, catechol, bisphenols such as bisphenol A, bisphenol F, bisphenol AD and bisphenol S, 4,4′-dihydroxybiphenyl, or bis(4-hydroxyphenyl)ether; and (meth)acrylate oligomers comprising an alkyl, aryl, methylol, allyl, cycloaliphatic, halogen (tetrabromo bisphenol A), or nitro group; and a polycyclic aromatic ring-containing epoxy resin, without being limited thereto.

A latent curing agent may be used, and may include an epoxy-type heat curing agent, without being limited thereto. For example, an epoxy-type heat curing agent known in the art may be used without limitation. The epoxy-type heat curing agent may include at least one selected from the group of imidazole, acid anhydride, amine, hydrazine, cationic curing agents, and combinations thereof

The composition for the anisotropic conductive film may further include hydrophobic nanosilica. The hydrophobic nanosilica may allow smooth adjustment of flowability under process conditions and may induce high strength of the cured structure of the anisotropic conductive film to reduce the possibility of and/or prevent expansion of the anisotropic conductive film at high temperature. The anisotropic conductive film may exhibit excellent initial adhesion and low connection resistance while maintaining connection and adhesion reliability under high temperature/high humidity and thermal impact conditions, thereby ensuring excellent durability for a long period of time.

The hydrophobic nanosilica particles may be prepared by surface treatment of an organic silane compound, and may have a particle size of about 5 nm to about 20 nm and a specific surface area of about 100 m²/g to about 300 m²/g. The silica particles may include at least one selected from Aerosil R-812, Aerosil R-972, Aerosil R-805, Aerosil R-202, Aerosil R-8200 (Degussa GmbH), and the like, without being limited thereto.

The organic silane compound used for surface treatment of nanosilica particles to exhibit hydrophobic properties may include at least one selected from the group of vinyltrichlorosilane, vinyltrimethoxysilane, 3-glycydoxypropyltrimethoxysilane, 3-methacryloxypropyltrimethoxysilane, dimethyldichlorosilane, octylsilane, hexamethyldisilazane, octamethylchlorotetrasiloxane, polydimethylsiloxane, 2-aminoethyl-3-aminopropylmethyldimethoxysilane, 3-ureidopropyltriethoxysilane, and the like.

The composition for the anisotropic conductive film may be used for, e.g., a COG ACF (a chip-on-glass anisotropic conductive film) for OLED devices (organic light emitting diode display devices).

Next, the constitution and operation of embodiments will be described in more detail with reference to examples. It should be understood that the following examples are provided for illustration only and are not to be construed in any way as limiting. Accordingly, the following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE 1

Preparation of anisotropic conductive film including two types of conductive particles having different hardness and surface protrusion density.

A composition for an anisotropic conductive film was prepared using the following components:

based on 100 parts by weight of anisotropic conductive film in terms of solid content,

1) Epoxy: 17 parts by weight of BPA (Bisphenol A) epoxy (Kukdo Chemical Co., Ltd.) and 19 parts by weight of polycyclic aromatic ring-containing epoxy resin (HP4032D, Dainippon Ink and Chemicals Inc.);

2) Silica particles: 4 parts by weight of nanosilica (R812, Degussa GmbH);

3) Curing agent: 35 parts by weight of core-shell type latent curing agent containing imidazole (Asahi Kasei Co., Ltd.);

4) First conductive particles: 29 parts by weight of nickel coated composite of the polymer resin and the silica (20% K-value: 10,000 N/mm², compressive strain: 15% upon thermal compression at 220° C. under a load of 110 MPa for 5 seconds, surface density of protrusion: 20/μm²); and

5) Second conductive particles: 6 part by weight of nickel coated polymer resin conductive particles (20% K-value: 6,000 N/mm², compressive strain: 25% upon thermal compression at 220° C. under a load of 110 MPa for 5 seconds; surface density of protrusion: 4/μm², Sekisui).

The prepared liquid composition was stirred at room temperature (25° C.) at a rate which could prevent pulverization of the conductive particles. The stirred mixture was thinly coated on a polyethylene terephthalate (PET) base film, which had been subjected to silicon surface release treatment, and dried by blowing hot air thereupon at 70° C. for 5 minutes to produce a 30 μm thick film. For fabrication of the film, a casting knife was used.

### COMPARATIVE EXAMPLE 1

Preparation of anisotropic conductive film including only first conductive particles as conductive particles

An anisotropic conductive film was prepared in the same manner as in

Example 1 except that the second conductive particles were not used and 35 parts by weight of the first conductive particles was used.

### COMPARATIVE EXAMPLE 2

Preparation of anisotropic conductive film including only second conductive particles as conductive particles.

An anisotropic conductive film was prepared in the same manner as in Example 1 except that the first conductive particles were not used and 35 parts by weight of the second conductive particles was used.

Table 1 shows the compositions of the anisotropic conductive films prepared in Example 1, and Comparative Examples 1 and 2 in terms of parts by weight.

TABLE 1

| | | Comparative | Comparative |
|---|---|---|---|
| Composition | Example 1 | Example 1 | Example 2 |
| BPA epoxy | 17 | 17 | 17 |
| HP4032D | 19 | 19 | 19 |
| Nanosilica | 4 | 4 | 4 |
| Curing agent | 35 | 35 | 35 |
| First conductive | 29 | 35 | — |
| particles | | | |
| Second conductive | 6 | — | 35 |
| particles | | | |
| Total | 100 | 100 | 100 |

### EXPERIMENTAL EXAMPLE 1

Measurement of Initial and Reliability Connection Resistance

To measure connection resistance of the anisotropic conductive films prepared in Example 1, and Comparative Examples 1 and 2, each of the anisotropic conductive films of Example 1, and Comparative Examples 1 and 2 was interposed between a glass substrate having a bump area of 2,000 μm² and a 2,000 Å thick titanium circuit and a 1.7 mm thick chip having a bump area of 2,000 μm2. Followed by compression and heating under conditions of 220° C. and 90 MPa for 5 seconds, thereby preparing 5 specimens for each of the 4 anisotropic conductive film samples.

1) Pre-compression condition: 70° C., 1 second, 1.0 MPa

2) Main-compression condition: 220° C., 5 seconds, 90 MPa

Initial connection resistance of each of the 5 specimens was measured using a 4-point probe method (corresponding to ASTM F43-64T), and an average initial connection resistance was calculated.

In addition, each of the 5 specimens was left at 85° C. and 85% RH for 500 hours for high temperature/high humidity reliability evaluation, and reliability connection resistance of each of the 5 specimens was measured according to ASTM D117 to obtain an average value thereof.

Table 2 shows measurement results of the initial and reliability connection resistance of the anisotropic conductive films prepared in Example 1 and Comparative Examples 1 and 2.

TABLE 2

| | | Compar- | Cmpar- |
|---|---|---|---|
| | | ative | ative |
| | Example 1 | Example 1 | Example 2 |
| Initial connection resistance (Ω) | 0.34 | 0.28 | 5.1 |
| Reliability connection resistance (Ω) | 2.7 | 2.4 | 10.3 |

### EXPERIMENTAL EXAMPLE 2

Evaluation of Visibility of Conductive Particles after Film Bonding

To evaluate visibility of bonding of the anisotropic conductive films of

Example 1, and Comparative Examples 1 and 2, each of the anisotropic conductive films was compressed under conditions of 200° C. and 4.0 MPa for 4 seconds, and evaluated as to whether deformation of the conductive particles could be confirmed through a microscope.

Evaluation results of visibility are provided with reference to FIG. 2.

According to Experimental Examples 1 and 2, as the amount of the first conductive particles exhibiting high hardness increased, the connection resistance was decreased, thereby providing improved connection performance. Accordingly, the anisotropic conductive film of Comparative Example 1 containing the largest amount of the first conductive particles exhibited superior connection performance to other films. However, since the anisotropic conductive film of Comparative Example 1 does not include the second conductive particles, it did not exhibit visibility.

### EXAMPLE 2

(1) Preparation of Composite of Polymer Resin and Silica

In a reactor, deionized water and a sodium lauryl sulfate emulsifying agent were placed in weighed amounts, stirred at 70° C. for 30 minutes under a nitrogen atmosphere, followed by addition of 26 g of styrene (Junsei Co., Ltd) as a polymer resin, 4 g of silica, and 1 g of a potassium persulfate aqueous solution to the mixture, thereby preparing a composite of the polymer resin and the silica having an average particle diameter of 2 μm.

(2) Preparation of Conductive Microspheres

The prepared composite of the polymer resin and the silica was etched in a chromium acid and sulfuric acid solution, dipped in a nickel chloride solution to form fine nuclei of nickel on the surface of the particles through reduction, followed by electroless nickel plating to form a conductive metal layer. Then, Ni microspheres having a diameter of 20 nm to 100 nm were deposited on the conductive metal layer, followed by plating with at least one of Au, Pd, and Ni, thereby preparing conductive microspheres.

(3) Preparation of Double-Layer Anisotropic Conductive Film

Detailed components used in Examples and Comparative Examples were as follows.

1. Binder system: Bisphenol A-type epoxy resin (YP-50, Kukdo Chemical Co., Ltd.)

2. Curing system: Polycyclic aromatic ring-containing epoxy resin (HP4032D, Dainippon Ink and Chemical Inc.)

3. Hydrophobic nanosilica: Nanosilica (R812, Degussa GmbH)

4. Latent curing agent: Imidazole microcapsule type ((HX3922HP, Asahi Kasei Co., Ltd.)

5. Conductive microsphere 1: Composite of nickel coated polymer resin and silica prepared in Example 2-(2) (20% K-value: 10,000 N/mm², compressive strain: 15% upon thermal compression at 220° C. under a load of 110 MPa for 5 seconds)

6. Conductive microsphere 2: Nickel coated polymer resin conductive particles (20% K-value: 5,000 N/mm², compressive strain: 30% upon thermal compression at 220° C. under a load of 110 MPa for 5 seconds, Sekisui)

7. Conductive microsphere 3: Nickel coated polymer resin conductive particles (20% K-value: 2,000 N/mm², compressive strain: 3% upon thermal compression at 220° C. under a load of 110 MPa for 5 seconds, NCI)

8. Silane coupling agent: gamma-glycidoxytrimethoxysilane

9. Solution for silane surface treatment: Solution prepared by diluting the binder system and gamma-glycidoxypropyltrimethoxysilane in a mixing ratio of 2:1 in a solvent to a concentration of 10%

10. Core-shell rubber: Butadiene rubber (Gantz)

Preparation of Anisotropic Conductive Film (ACF)

The binder system, the curing system, the conductive microspheres prepared in

Example 2-(2), the silica, the latent curing agent, and the silane coupling agent were mixed in amounts as listed in Table 3 with 50 parts by weight of a solvent (PGMEA), thereby preparing a composition for an anisotropic conductive film. The composition was coated to a thickness of 20 μm on a base film, and 0.1 ml of the solution for silane surface treatment was uniformly sprayed to the surface of the film. Then, the composition was dried at 70° C. for 5 minutes, thereby preparing a desired anisotropic conductive film.

b. Preparation of Non-Conductive Film (NCF)

The binder system, the curing system, the silica, the latent curing agent, and the silane coupling agent were mixed in amounts as listed in Table 3 with 50 parts by weight of a solvent (PGMEA), thereby preparing a composition for an insulation adhesive layer. Then, the composition was coated to a thickness of 10 μm on a base film. Then, the composition was dried at 70° C. for 5 minutes, thereby preparing a non-conductive film of the anisotropic conductive film.

c. Preparation of Double-Layer Anisotropic Conductive Film

The prepared conductive anisotropic conductive film and non-conductive film were bonded to each other at 40° C. under a load of 1 MPa through a laminating process, thereby preparing a double-layer anisotropic conductive film of Example 2 in which the anisotropic conductive film is stacked on the non-conductive film.

### COMPARATIVE EXAMPLES 3 AND 4

Double-layer anisotropic conductive films were prepared in the same manner as in Example 2 except for the compositions as listed in Table 3 (unit: wt % in solid content).

TABLE 3

| | ACF | | | |
|---|---|---|---|---|
| | Exam- | Comparative | Comparative | |
| Composition | ple 2 | Example 3 | Example 4 | NCF |
| Binder system | 17 | 17 | 17 | 26 |
| Curing system | 19 | 19 | 19 | 26 |
| Hydrophobic nanosilica | 4 | 4 | 4 | 3 |
| Latent curing agent | 28 | 28 | 28 | 32 |
| Conductive microsphere 1 | 30 | | | |
| Conductive microsphere 2 | | 30 | | |
| Conductive microsphere 3 | | | 30 | |
| Silane coupling agent | 2 | 2 | 2 | 2 |
| Core shell rubber | 0 | 0 | 0 | 10 |
| Total | 100 | 100 | 100 | 100 |

The films prepared in Example 2, and Comparative Examples 3 to 4, were evaluated as to connection resistance and post-reliability test connection resistance of an ACF layer according to the following method. Results are shown in Table 4.

<Evaluation of Physical Properties>

1. Initial connection resistance: As adherents, a driver IC chip having a bump area of 1,430 μm² and a glass substrate having a 2,000 Å thick circuit were used. Here, the uppermost layer of terminals was comprised of titanium. Each of the prepared films was placed between the adherents and thermally compressed under conditions of 220° C. and 110 MPa for 5 seconds to prepare a sample. Electric resistance of the sample was measured by applying an electric current of 1 mA using a HIOKI HI-tester (HIOKI Co., Ltd.).

2. Connection resistance after reliability test: The prepared sample was left under conditions of high temperature and high humidity (85° C./85% RH) for 500 hours, and connection resistance of the sample was measured by applying an electric current of 1 mA using a HIOKI HI-tester (HIOKI Co., Ltd.).

TABLE 4

| | ACF | | |
|---|---|---|---|
| | | Comparative | Comparative |
| | Example 2 | Example 3 | Example 4 |
| Connection resistance | 0.28 | 0.82 | 0.29 |
| (initial) | | | |
| Connection resistance | 2.4 | 5.7 | 5400 |
| (after reliability test) | | | |

From Table 4, it could be seen that the conductive microspheres and the anisotropic conductive film including the same exhibited good electrical properties in terms of initial connection resistance and post-reliability connection resistance.

### EXAMPLE 3

### Preparation of Double-Layer Anisotropic Conductive Film

(1) Preparation of Second Conductive Layer Film

30 parts by weight of a binder (YP50, Kukdo Chemical Co., Ltd.), 32 parts by weight of an epoxy resin (RKB4110, Resinous Product Company), 1 part by weight of a coupling agent (KBM403, Shinetsu Co., Ltd.), 27 parts by weight of a latent curing agent (HX3941, Asahi Kasei Co., Ltd.), 5 parts by weight of second conductive particles (AUEL003, Sekisui, 20% k-value: 1900 N/mm²), and 100 parts by weight of a solvent PGMEA were mixed. Then, the prepared mixture was coated on a release film and dried in an oven at 70° C. to volatize the solvent, thereby preparing a 10 μm thick non-conductive film.

(2) Preparation of First Conductive Layer Film

23 parts by weight of a binder (YP50, Kukdo Chemical Co., Ltd.), 26 parts by weight of a liquid epoxy resin (RKB4110, Resinous Product Company), 1 part by weight of a coupling agent (KBM403, ShinEtsu Co., Ltd.), 20 parts by weight of a latent curing agent (HX3941, Asahi Kasei Co., Ltd.), 30 parts by weight of first conductive particles (PNR and Nippon Chemical Industry, 20% k-value: 7000 N/mm²), and 100 parts by weight of a solvent PGMEA were mixed. Then, the prepared mixture was coated on a release film and dried in an oven at 70° C. to volatize the solvent, thereby preparing a 10 μm thick anisotropic conductive film.

(3) Preparation of Double-Layer Anisotropic Conductive Film

The prepared first conductive layer film and the second conductive layer films were bonded to each other under conditions of 40° C. and 0.2 Mpa through a laminating process, thereby preparing a double-layer anisotropic conductive film of Example 3 in which the anisotropic conductive film is stacked on the non-conductive film.

### EXAMPLE 4

### Preparation of Double-Layer Anisotropic Conductive Film

A double-layer anisotropic conductive film was prepared in the same manner as in Example 3 except that the second conductive particles were added in an amount of 10 parts by weight.

### EXAMPLE 5

### Preparation of Double-Layer Anisotropic Conductive Film

A double-layer anisotropic conductive film was prepared in the same manner as in Example 3 except that the second conductive particles were added in an amount of 15 parts by weight.

### COMPARATIVE EXAMPLES 5 TO 8

Double-layer anisotropic conductive films were prepared in the same manner as in Example 3 except for the compositions as listed in Table 3 (unit: wt % in solid content).

TABLE 5

| | | | | | Comparative | Comparative | Comparative | Comparative |
|---|---|---|---|---|---|---|---|---|
| | | Example 3 | Example 4 | Example 5 | Example 5 | Example 6 | Example 7 | Example 8 |
| ACF | A | 23 | 23 | 23 | 23 | 23 | 23 | 23 |
| layer | B | 26 | 26 | 26 | 26 | 26 | 26 | 26 |
| | C | 1 | 1 | 1 | 1 | 1 | 1 | 1 |
| | D | 20 | 20 | 20 | 20 | 20 | 20 | 20 |
| | E | 30 | 30 | 30 | 30 | 30 | 30 | 30 |
| | F | — | — | — | 5 | 10 | 15 | |
| NCF | A | 30 | 30 | 30 | 30 | 30 | 30 | 30 |
| layer | B | 32 | 32 | 32 | 32 | 32 | 32 | 32 |
| | C | 1 | 1 | 1 | 1 | 1 | 1 | 1 |
| | D | 27 | 27 | 27 | 27 | 27 | 27 | 27 |
| | F | 5 | 10 | 15 | | | | |

A: Binder-Phenoxy resin (YP50, Kukdo Chemical Co., Ltd.)
B: Epoxy resin (RKB, Resinous Product Company)
C: Silane coupling agent (KBM403, Shinetsu Co., Ltd.)
D: Latent curing agent-Imidazole curing agent (HX3941, Asahi Kasei Co., Ltd.)
E: First conductive particles (PNR, Japan Chemical Industry Inc.)-(20% k-value: 7000 N/mm²)
F: Second conductive particles (AUEL003, Sekisui)-(20% k-value: 1900 N/mm²)

The prepared compositions and film of Examples 3 to 5 and Comparative Examples 5 to 8 were evaluated as to ACF viscosity, ACF coating state, degree of dispersion of the first conductive particles/second conductive particles, pre-compression temperature, post-bonding resistance and post-bonding visibility of particles by the following methods. Results are shown in Table 6.

<Evaluation of Physical Properties>

(1) ACF viscosity: The viscosity of the composition of the ACF before drying was measured using a No. 6 spindle of a Brookfield viscometer at 25° C. and 60 rpm.

(2) ACF coating state: Stripes, nodules, stains, dents, scratches, and the like on the ACF upon coating were observed through visual inspection with the naked eye. After coating, the anisotropic conductive film was maintained in a thickness variation of 1 micrometer or less and an area-based diameter of 1 mm or less.

(3) Degree of dispersion of first conductive particles/second conductive particles within ACF: After being coated on the double-layer anisotropic conductive film, the number of first conductive particles and the number of second conductive particles were directly counted on a micrograph, and the degree of dispersion was calculated by the following equation.

Degree of dispersion=(Number of second conductive particles/number of first conductive particles)×100

(4) Pre-compression temperature: It was confirmed through visual inspection with the naked eye whether the ACF was suitably attached to the panel when the base film was stripped off after compressing the ACF while measuring the temperature of the ACF. Table 2 shows the pre-compression temperature at which the ACF was suitably attached to the panel. When the ACF was detached from the panel due to low adhesion, the pre-compression temperature was raised until the ACF remained in an attached state to the panel.

(5) Post-bonding resistance: Each of the anisotropic conductive films prepared in the examples and the comparative examples was left at 25° C. for 1 hour, followed by evaluation of post-bonding resistance using a 50 μm pitch OLB TEG and TIO glass substrate, COF, and TCP (tape carrier package). After pre-compressing the anisotropic conductive film on the terminals of the OLB circuit under conditions of 50° C. and 1 MPa for 1 second, the release film was removed. Then, the anisotropic conductive film was subjected to main compression with respect to the COF circuit terminals under conditions of 180° C. and 3 MPa for 5 seconds. Seven specimens for each sample were prepared, and employed to measure connection resistance by a 4-point probe method (according to ASTM F43-64T).

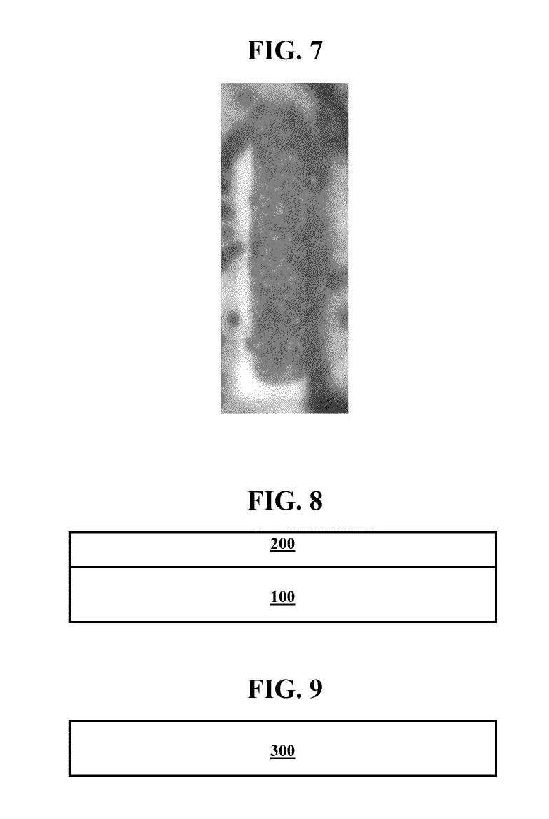

(6) Post-bonding visibility of particles: After bonding, breakage of the particles on the bumps was confirmed using an optical microscope (Olympus Co., Ltd.), with windows open at input/output terminals. When the particles were opaque, it was determined that the particles exhibited poor visibility, and when the particles were transparent, it was determined that the particles exhibited good visibility. One example of good visibility is shown in FIG. 6 (Example 4), and one example of poor visibility is shown in FIG. 7 (Comparative Example 8).

TABLE 6

| | | | | Comparative | Comparative | Comparative | Comparative |
|---|---|---|---|---|---|---|---|
| | Example 3 | Example 4 | Example 5 | Example 5 | Example 6 | Example 7 | Example 8 |
| ACF viscosity | 5,000 cps | 5,000 cps | 5,000 cps | 8,000 cps | 12,000 cps | 15,000 cps | 5,000 cps |
| | | | | | | Filter | |
| | | | | | | Difficulty | |
| ACF coating state | ◯ | ◯ | ◯ | Δ | X | X | ◯ |
| | | | | | Stripe and | Scratch | |
| | | | | | dent | | |
| Degree of dispersion | 35000 ± 2000 | 35000 ± 2000 | 35000 ± 2000 | 41000 ± 5000 | 47000 ± 10000 | Non- | 35000 ± 2000 |
| of first conductive | | | | | | uniform | |
| particles/second | | | | | | dispersion | |
| conductive particles | | | | | | | |
| within ACF | | | | | | | |
| Pre-compression | 50° C. or | 50° C. or | 50° C. or | 80° C. or | 100° C. or | 120° C. or | 50° C. or |
| temperature | more | more | more | more | more | more | more |
| Post-bonding | 1 Ω or less | 1 Ω or less | 1 Ω or less | 1 Ω or less | 1 Ω or less | 1 Ω or less | 1 Ω or less |
| resistance | | | | | | | |
| Post-bonding | ⊚ | ⊚ | ⊚ | ◯ | ◯ | X | X |
| visibility | | | | | | | |

From Table 6, it could be seen that the anisotropic conductive film according to Examples 3, 4, and 5, had improved physical properties in terms of visibility, viscosity, dispersion, and flowability, and also allowed pre-compression at low temperature. Further, the anisotropic conductive film according to embodiments had low pre-compression temperature, thereby providing excellent adhesion and electrical properties including connection resistance and insulation resistance.

By way of summation and review, anisotropic conductive adhesives may be suitable to be used as connecting materials for circuit terminals when forming circuit connections for various displays and semiconductor devices. Further, conductive microspheres have been made in the form of carbon fibers, solder balls, and the like. The conductive microspheres may be prepared in the form of metallic balls such as nickel or silver balls. Another method of forming the conductive microspheres includes coating spherical resin particles with nickel, gold or palladium, and/or by processing the spherical resin particles with another material.

An anisotropic conductive film used for electrical connection between a driver IC and a glass panel may be referred to as a COG (chip-on-glass) ACF. Under conditions of high temperature and high pressure, the COG ACF is bonded between the driver IC and the glass panel such that gold bumps of the driver IC may be electrically connected to terminals on the glass panel via deformed conductive particles. Further, it is desirable that the conductive particles of a COG ACF for LCDs have relatively low hardness and the conductive particles of a COG ACF for OLEDs have relatively high hardness. In this regard, for an LCD, in which the uppermost layer of terminals on the panel may be composed of indium tin oxide (ITO), the conductive particles having large deformability in a suitable range may provide a wide contact area. For an OLED, in which the uppermost layer of terminals on the panel may be composed of metal, the conductive particles having high hardness may penetrate an oxide layer on the metal.

Further, to identify whether a connection of an anisotropic conductive film is successful, deformation of the conductive particles may be observed. However, when hard conductive particles are used, the conductive particles may not be substantially deformed, thereby making it difficult to identify connection of the anisotropic conductive film. Further, when a large number of protrusions are formed on the surfaces of the particles, diffusive reflection may occur on the surfaces of the particles, which makes observation of the particles more difficult, thereby deteriorating visibility.

In addition, conductive microspheres having high hardness tend to exhibit low deformability upon compression and generate compressive force when compressed between the terminals of the panel and bumps of the driver IC. In this case, the compressive force may be transferred to the panel and the driver IC, causing physical damage and connection failure. Accordingly, the use of conductive particles having high hardness and formed on the surface thereof with a large number of protrusions results in low visibility, thereby making identification of connection of the anisotropic conductive film difficult.

In view of the above, embodiments relate to providing conductive microspheres, which exhibit excellent electrical connection performance, and an anisotropic conductive film including the same. In this regard, to stably achieve maximization of a contact area between electrodes, while ensuring good connection therebetween, it is desirable for the particles to exhibit hardness at an initial compression stage and to be suitably deformed as compression proceeds.

Accordingly, embodiments relate to a semiconductor device connected by an anisotropic conductive film including conductive microspheres in which first conductive particles have high hardness and second conductive particles have low hardness. Thus, the first conductive particles may provide low connection resistance and the second conductive particles permit identification of a connection result and measurement of a suitable bonding pressure, thereby providing enhanced connection performance and effective visibility.

Embodiments also relate to a semiconductor device connected by an anisotropic conductive film, in which a low visibility and difficulty in identification of film connection due to insignificant deformation of conductive particles in view of having relatively high hardness and/or a relatively large number of protrusions on surfaces thereof, may be avoided.

Embodiments further relate to providing conductive microspheres and an anisotropic conductive film including the same, which have sufficient hardness to penetrate a metal oxide layer to provide good connectivity while exhibiting compression deformability so as not to cause physical damage to terminals or bumps. Accordingly, the conductive microspheres may provide an increased contact area between connection substrates upon compression, thereby providing excellent conductivity.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A semiconductor device, comprising:
an anisotropic conductive film for connecting the semiconductor device, the anisotropic conductive film including:
a first conductive layer having first conductive particles, the first conductive particles including cores containing silica or a silica composite, and having a 20% K-value ranging from about 7,000 N/mm² to about 12,000 N/mm².

2. The semiconductor device as claimed in claim 1, wherein the first conductive particles have a compressive strain ranging from about 5% to about 40% upon thermal compression of the anisotropic conductive film under conditions of 220° C. and 110 Mpa for 5 seconds.

3. The semiconductor device as claimed in claim 1, wherein the cores include the silica composite, the silica composite including a polymer resin and silica, the polymer resin being a polymer of at least one monomer selected from the group of a crosslinking polymerizable monomer and a mono-functional monomer.

4. The semiconductor device as claimed in claim 3, wherein the polymer resin includes the crosslinking polymerizable monomer, the crosslinking polymerizable monomer including at least one selected from the group of a vinyl benzene monomer, allyl compound monomer and an acrylate monomer.

5. The semiconductor device as claimed in claim 3, wherein the polymer resin includes the mono-functional monomer, the mono-functional monomer including at least one selected from the group of a styrene monomer, a (meth)acrylate monomer, vinyl chloride, vinyl acetate, vinyl ether, vinyl propionate, and vinyl butyrate.

6. The semiconductor device according as claimed in claim 3, wherein the silica composite includes about 15 wt % to about 90 wt % of silica based on a total amount of the silica composite.

7. The semiconductor device as claimed in claim 1, wherein the first conductive particles have an average particle diameter of about 0.1 μm to about 200 μm.

8. The semiconductor device according as claimed in claim 1, wherein the first conductive particles include conductive shells on the cores.

9. The semiconductor device as claimed in claim 1, wherein the first conductive particles have protrusions on surfaces thereof.

10. The semiconductor device as claimed in claim 1, wherein:
the anisotropic conductive film further includes second conductive particles having a second 20% K-value different from the 20% K-value of the first conductive particles, the second 20% K-value ranging from about 3,000 N/mm² to about 7,000 N/mm², and
a difference between the 20% K-value of the first conductive particles and the second 20% K-value of the second conductive particles is less than about 5,000 N/mm².

11. The semiconductor device as claimed in claim 10, wherein the second conductive particles have cores including a polymer resin.

12. The semiconductor device as claimed in claim 10, wherein the first conductive particles have about 10 to about 40 protrusions per unit surface area on surfaces thereof.

13. The semiconductor device as claimed in claim 10, wherein the second conductive particles have 0 to about 10 protrusions per unit surface area on surfaces thereof.

14. The semiconductor device as claimed in claim 10, wherein the second conductive particles are present in an amount of about 1 to about 30 parts by weight based on 100 parts by weight of a total amount of conductive particles.

15. The semiconductor device as claimed in claim 1, wherein:
the anisotropic conductive film further includes a second conductive layer on the first conductive layer, and
the second conductive layer includes second conductive particles, a first hardness of the first conductive particles being higher that a second hardness of the second conductive particles.

16. The semiconductor device as claimed in claim 15, wherein a difference between the 20% K-value of the first conductive particles and a second 20% K-value of the second conductive particles is about 5,000 N/mm² or more.

17. The semiconductor device as claimed in claim 1, wherein:
the anisotropic conductive film further includes a second conductive layer on the first conductive layer, and
a first surface roughness of the first conductive particles is greater that a second surface roughness of the second conductive particles.

18. A semiconductor device, comprising:
a wiring substrate having a metal and metal oxide layer placed on an outermost layer thereof;
an anisotropic conductive film attached to a chip mounting surface of the wiring substrate; and
a semiconductor chip mounted on the anisotropic conductive film, wherein:
the anisotropic conductive film directly adjoins the metal and metal oxide layer and includes a first conductive layer including first conductive particles, and
the first conductive particles have a 20% K-value from about 7,000 N/mm² to about 12,000 N/mm², and have a compressive strain from about 5% to about 40% upon thermal compression of the anisotropic conductive film under conditions of 220° C. and 110 Mpa for 5 seconds.

19. The semiconductor device as claimed in claim 18, wherein the anisotropic conductive film further includes second conductive particles having a second 20% K-value that is lower than the 20% K-value of the first conductive particles.

20. The semiconductor device as claimed in claim 18, wherein the anisotropic conductive film includes a second conductive layer on the first conductive layer, the second conductive layer including second conductive particles that have a second 20% K-value that is lower than the 20% K-value of the first conductive particles.

21. The semiconductor device as claimed in claim 18, wherein the first conductive particles include protrusions on surfaces thereof.
